(19) United States
(12) Patent Application Publication
(10) Pub. No.: US 2025/0271116 A1
(43) Pub. Date: Aug. 28, 2025

(54) MICROLED AND MICROLENS ASSEMBLY

(71) Applicant: Lumileds LLC, San Jose, CA (US)

(72) Inventor: Hisashi Masui, Newark, CA (US)

(73) Assignee: Lumileds LLC, San Jose, CA (US)

(21) Appl. No.: 19/206,306

(22) Filed: May 13, 2025

Related U.S. Application Data
(63) Continuation of application No. PCT/US2023/037157, filed on Nov. 10, 2023.
(60) Provisional application No. 63/432,778, filed on Dec. 15, 2022.

(51) Int. Cl. F21V 5/00; F21Y 113/17; F21Y 115/10

(52) U.S. Cl. CPC F21V 5/007; F21Y 2113/17; F21Y 2115/10

(57) ABSTRACT

A light source comprises microLEDs of two or more colors in combination with a shared microlens, arranged to compensate for chromatic aberration of the microlens by placing the microLEDs at different distances from the microlens. The microLEDs that emit shorter wavelength light are placed closer to the microlens than the microLEDs that emit longer wavelengths of light. A display comprises a microlens array and a plurality of pixels, with each pixel paired with one of the microlenses and the microLEDs within a pixel arranged to compensate for chromatic aberration of the pixel's lens. The inventor has recognized that the focal length of a microlens for blue light may differ from that for red light by approximately the same magnitude as the thickness of a microLED epitaxial structure. Hence the variation in distances required to achieve compensation for chromatic aberration of the microlens may be readily achieved in the fabrication of a microLED array.

### CROSS-REFERENCE TO RELATED APPLICATIONS

This application is a continuation of PCT Application PCT/US2023/037157 filed on Nov. 10, 2023 and titled “MICROLED AND MICROLENS ASSEMBLY,” which claims benefit of priority to U.S. Provisional Patent Application 63/432,778 filed on Dec. 15, 2022 and titled “MICROLED AND MICROLENS ASSEMBLY.” All of the above applications are incorporated herein by reference in their entirety.

### FIELD OF THE INVENTION

The invention relates generally to microLEDs, microlenses, displays comprising an array of microLEDs associated with a microlens array, and visualization systems comprising such displays.

### BACKGROUND

Semiconductor light emitting diodes and laser diodes (collectively referred to herein as “LEDs”) are among the most efficient light sources currently available. The emission spectrum of an LED typically exhibits a single narrow peak at a wavelength determined by the structure of the device and by the composition of the semiconductor materials from which it is constructed. By suitable choice of device structure and material system, LEDs may be designed to operate at ultraviolet, visible, or infrared wavelengths.

LEDs may be combined with one or more wavelength converting materials (generally referred to herein as “phosphors”) that absorb light emitted by the LED and in response emit light of a longer wavelength. For such phosphor-converted LEDs (“pcLEDs”), the fraction of the light emitted by the LED that is absorbed by the phosphors depends on the amount of phosphor material in the optical path of the light emitted by the LED, for example on the concentration of phosphor material in a phosphor layer disposed on or around the LED and the thickness of the layer. Phosphor-converted LEDs may be designed so that all the light emitted by the LED is absorbed by one or more phosphors, in which case the emission from the pcLED is entirely from the phosphors. In such cases the phosphor may be selected, for example, to emit light in a narrow spectral region that is not efficiently generated directly by an LED. Alternatively, pcLEDs may be designed so that only a portion of the light emitted by the LED is absorbed by the phosphors, in which case the emission from the pcLED is a mixture of light emitted by the LED and light emitted by the phosphors. By suitable choice of LED, phosphors, and phosphor composition, such a pcLED may be designed to emit, for example, white light having a desired color temperature and desired color-rendering properties.

Inorganic LEDs and pcLEDs have been widely used to create different types of displays, for example augmented-reality (AR) displays, virtual-reality (VR) displays, mixed-reality (MR) displays (AR, VR, and MR systems referred to herein as visualization systems), smart glasses and displays for mobile phones, smart watches, monitors and TVs. Individual LEDs or pcLEDs in these architectures can have an area of a few square millimeters down to a few square micrometers (e.g., microLEDs) depending on the display size and its pixel per inch requirements.

### SUMMARY

This specification discloses light sources comprising microLEDs of two or more colors in combination with a shared microlens, arranged to compensate for chromatic aberration of the microlens. A microlens is a small lens typically having a diameter less than a millimeter. Chromatic aberration is the failure of a lens to focus all colors of light in a collimated beam to the same point, i.e., the focal length of the lens varies with the wavelength of light. Reciprocally, chromatic aberration is the failure of a lens to equivalently collimate light of different wavelengths emitted from the same point. Instead, beams of light of different color formed by the lens from light emitted from the same point will have different divergences. Chromatic aberration of a lens results from dispersion (wavelength dependence) of the refractive index of the material from which the lens is made. For visible and near infrared light, the refractive index of lens materials is larger at shorter wavelengths (e.g., blue light) than at longer wavelengths (e.g., red light).

The light sources disclosed in this specification compensate for the chromatic aberration of the shared microlens by placing the microLEDs at different distances from the microlens, with the microLEDs that emit shorter wavelength light placed closer to the microlens than the microLEDs that emit longer wavelengths of light. For example, each microLED may be placed at a distance from the microlens equal or about equal to the focal length of the microlens for the wavelength of light emitted by the microLED. This results in a beam for which the light emitted by the different color microLEDs is equivalently collimated. The microLEDs may be placed slight closer than the wavelength dependent focal lengths if a diverging rather than collimated beam is desired.

The inventor has recognized that the focal length of a microlens for blue light may differ from that for red light by approximately the same magnitude as the thickness of a microLED epitaxial structure. Hence the variation in distances required to achieve compensation for chromatic aberration of the microlens may be readily achieved in the fabrication of a microLED array.

Display devices comprising microLED pixels (e.g., R, G, B pixels) in combination with microlenses in which chromatic aberration is compensated for as just described will produce better (e.g., sharper) images than conventional displays.

In one variation, a light source comprises a microlens, a first microLED, a second microLED, and a third microLED. The first microLED comprises a light emitting surface and is configured to emit light having a first peak wavelength through its light emitting surface toward the microlens. The first microLED is arranged with its light emitting surface at a first distance from the microlens for which the microlens collimates or partially collimates light at the first peak wavelength emitted by the first microLED through its light emitting surface.

The second microLED comprises a light emitting surface and is configured to emit light having a second peak wavelength through its light emitting surface toward the microlens. The second microLED is arranged with its light emitting surface at a second distance from the microlens for which the microlens collimates or partially collimates light at the second peak wavelength emitted by the second microLED through its light emitting surface.

The third microLED comprises a light emitting surface and is configured to emit light having a third peak wavelength through its light emitting surface toward the microlens. The third microLED is arranged with its light emitting surface at a third distance from the microlens for which the microlens collimates or partially collimates light at the third peak wavelength emitted by the third microLED through its light emitting surface.

The second peak wavelength is longer than the first peak wavelength and the second distance is longer than the first distance. The third peak wavelength is longer than the second peak wavelength and the third distance is longer than the second distance.

The differences in length between the first distance, the second distance, and the third distance may at least partially compensate for chromatic aberration exhibited by the microlens.

The first peak wavelength, the second peak wavelength, and the third peak wavelength may for example all be visible light wavelengths. For example, the first peak wavelength may be a blue light wavelength and the third peak wavelength a red light wavelength.

The difference in length between the first distance and the third distance may be for example about 3 microns to about 7 microns, for example about 5 microns.

The light emitting surface of the first microLED, the light emitting surface of the second microLED, and the light emitting surface of the third microLED may be displaced from each other perpendicular to an optical axis of the microlens.

The second microLED may be stacked on the third microLED and the first microLED may be stacked on the second microLED.

The microLEDs may be direct emitting microLEDs or wavelength converted microLEDs. The light source may comprise one or more direct emitting microLEDs and one or more wavelength converted microLEDs.

The microlens may have a diameter perpendicular to its optical axis of, for example, about 4 microns to about 200 microns. The microlens may have a focal length of, for example, about 1 millimeter (mm) to about 20 mm.

In another variation, a display comprises a substrate, a microlens array comprising a plurality of microlenses, and a plurality of pixels disposed on the substrate. Each pixel is paired with a different one of the microlenses. Each pixel comprises a first microLED, a second microLED, and a third microLED.

The first microLED comprises a light emitting surface and is configured to emit light having a first peak wavelength through its light emitting surface toward the pixel's microlens. The first microLED is arranged with its light emitting surface at a first distance from the pixel's microlens for which the microlens collimates or partially collimates light at the first peak wavelength emitted by the first microLED through its light emitting surface.

The second microLED comprises a light emitting surface and is configured to emit light having a second peak wavelength through its light emitting surface toward the pixel's microlens. The second microLED is arranged with its light emitting surface at a second distance from the pixel's microlens for which the microlens collimates or partially collimates light at the second peak wavelength emitted by the second microLED through its light emitting surface. The second peak wavelength is longer than the first peak wavelength and the second distance is longer than the first distance.

The third microLED comprises a light emitting surface and is configured to emit light having a third peak wavelength through its light emitting surface toward the pixel's microlens. The third microLED is arranged with its light emitting surface at a third distance from the pixel's microlens for which the microlens collimates or partially collimates light at the third peak wavelength emitted by the third microLED through its light emitting surface. The third peak wavelength is longer than the second peak wavelength and the third distance is longer than the second distance.

For each pixel, the differences in length between the first distance, the second distance, and the third distance may at least partially compensate for chromatic aberration exhibited by the pixel's microlens.

For each pixel, the first peak wavelength, the second peak wavelength, and the third peak wavelength may for example all be visible light wavelengths. For example, the first peak wavelength may be a blue light wavelength and the third peak wavelength a red light wavelength.

For each pixel, the difference in length between the first distance and the third distance may be for example about 3 microns to about 7 microns, for example about 5 microns.

The pixels may be arranged on the substrate with a center-to-center pitch for adjacent pixels of, for example, about 4 microns to about 200 microns.

These and other embodiments, features and advantages of the present invention will become more apparent to those skilled in the art when taken with reference to the following more detailed description of the invention in conjunction with the accompanying drawings that are first briefly described.

### BRIEF DESCRIPTION OF THE DRAWINGS

FIG. 1 shows a schematic cross-sectional view of an example pcLED.

FIGS. 2A and 2B show, respectively, cross-sectional and top schematic views of an array of pcLEDs. FIG. 2C shows a schematic top view of an LED wafer from which LED arrays such as those illustrated in FIGS. 2A and 2B may be formed.

FIG. 3 schematically illustrates an example display system.

FIG. 4 shows a block diagram of an example visualization system.

FIG. 5A, FIG. 5B, and FIG. 5C show schematic cross-sectional views of example light sources comprising microLEDs of different colors in combination with a shared microlens, arranged to compensate for chromatic aberration of the microlens.

FIGS. 6A and 6B show, respectively, schematic cross-sectional and top views of a display comprising a microlens array and a plurality of pixels, with each pixel paired with one of the microlenses and the microLEDs within a pixel arranged to compensate for chromatic aberration of the pixel's lens.

FIG. 7 shows a schematic cross-sectional view of a device comprising a single lens and a plurality of pixels, with the microLEDs within each pixel arranged to compensate for chromatic aberration of the pixel's lens.

### DETAILED DESCRIPTION

The following detailed description should be read with reference to the drawings, in which identical reference numbers refer to like elements throughout the different figures. The drawings, which are not necessarily to scale, depict selective embodiments and are not intended to limit the scope of the invention. The detailed description illustrates by way of example, not by way of limitation, the principles of the invention.

FIG. 1 shows an example of an individual pcLED 100 comprising a light emitting semiconductor diode (LED) structure 102 disposed on a substrate 104, and a phosphor layer 106 (which may also be referred to herein as a wavelength converting structure) disposed on the LED. Light emitting semiconductor diode structure 102 typically comprises an active region disposed between n-type and p-type layers. Application of a suitable forward bias across the diode structure results in emission of light from the active region. The wavelength of the emitted light is determined by the composition and structure of the active region.

The LED may be, for example, a III-Nitride LED that emits ultraviolet, blue, green, or red light. LEDs formed from any other suitable material system and that emit any other suitable wavelength of light may also be used. Other suitable material systems may include, for example, III-Phosphide materials, III-Arsenide materials, and II-VI materials.

Any suitable phosphor materials may be used, depending on the desired optical output and color specifications from the pcLED. Phosphor layers may for example comprise phosphor particles dispersed in or bound to each other with a binder material or be or comprise a sintered ceramic phosphor plate.

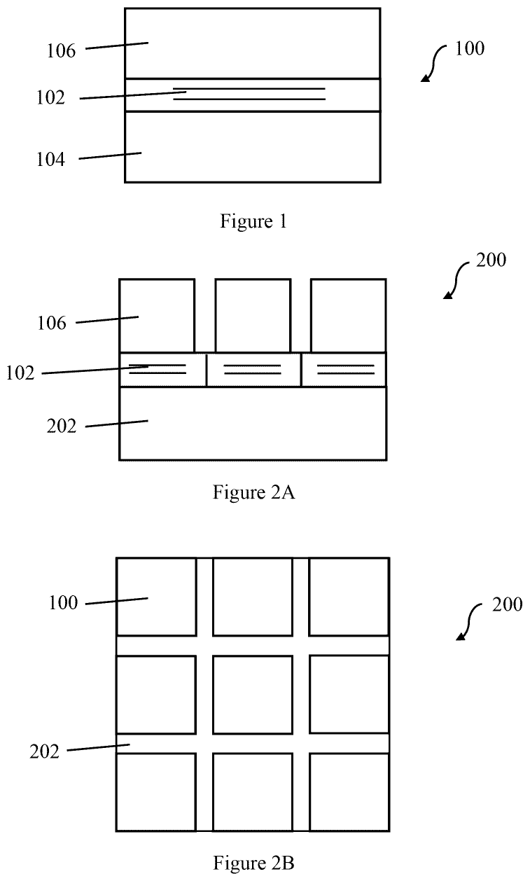

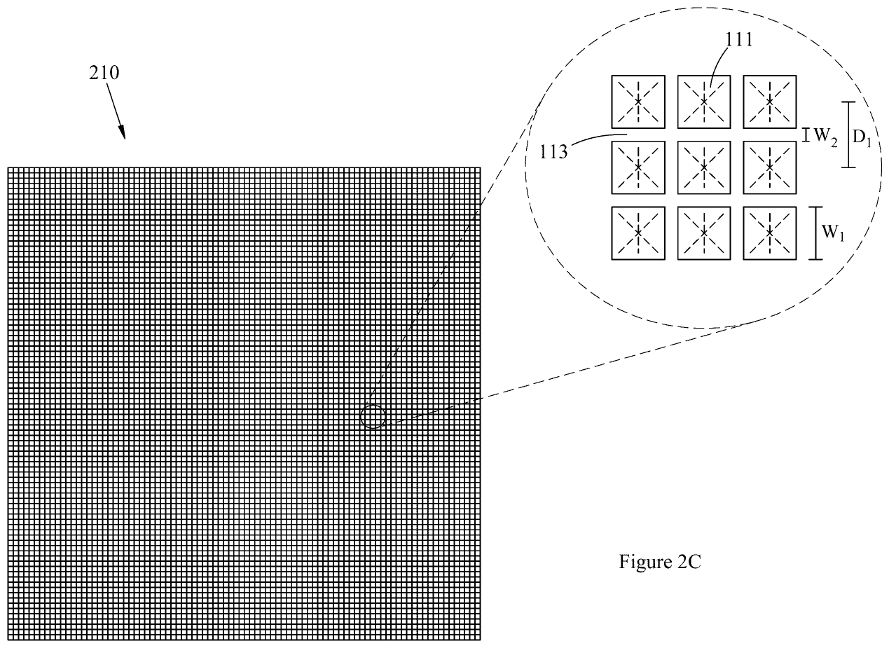

FIGS. 2A-2B show, respectively, cross-sectional and top views of an array 200 of pcLEDs 100 including phosphor layers 106 disposed on a substrate 202. Such an array may include any suitable number of pcLEDs arranged in any suitable manner. An array of LED or pcLEDs may be formed monolithically on a shared substrate, but alternatively an array of LEDs or pcLEDs may be formed from individual mechanically separate LEDs or pcLEDs. Substrate 202 may optionally comprise CMOS circuitry for driving the LEDs and may be formed from any suitable materials.

Although FIGS. 2A-2B show a three-by-three array of nine pcLEDs, such arrays may include for example tens, hundreds, or thousands of LEDs or pcLEDs. Individual LEDs or pcLEDs may have widths (e.g., side lengths) in the plane of the array of, for example, less than or equal to 1 millimeter (mm), less than or equal to 500 microns, less than or equal to 100 microns, less than or equal to 50 microns, or less than or equal to 10 microns. LEDs in such an array may be spaced apart from each other by streets or lanes having a width in the plane of the array of, for example, hundreds of microns, less than or equal to 100 microns, less than or equal to 50 microns, less than or equal to 10 microns, or less than or equal to 5 microns. Although the illustrated examples show rectangular LEDs or pcLEDs arranged in a symmetric matrix, the LEDs or pcLEDs and the array may have any suitable shape or arrangement and need not all be of the same shape or size. For example, LEDs or pcLEDs located in central portions of an array may be larger than those located in peripheral portions of the array. Alternatively, LEDs or pcLEDs located in central portions of an array may be smaller than those located in peripheral portions of the array.

FIG. 2C shows a schematic top view of a portion of an LED wafer 210 from which LED arrays such as those illustrated in FIGS. 2A and 2B may be formed. FIG. 2C also shows an enlarged 3×3 portion of the wafer. In the example wafer individual LEDs or pcLEDs 111 having side lengths (e.g., widths) of W₁ are arranged as a square matrix with neighboring LEDs or pcLEDs having a center-to-center distances D₁ and separated by lanes 113 having a width W₂. W₁ may be, for example, less than or equal to 1 millimeter (mm), less than or equal to 500 microns, less than or equal to 100 microns, less than or equal to 50 microns, or less than or equal to 10 microns. W₂ may be, for example, hundreds of microns, less than or equal to 100 microns, less than or equal to 50 microns, less than or equal to 10 microns, or less than or equal to 5 microns. D₁=W₁+W₂.

An array may be formed, for example, by dicing wafer 210 into individual LEDs or pcLEDs and arranging the dice on a substrate. Alternatively, an array may be formed from the entire wafer 210, or by dividing wafer 210 into smaller arrays of LEDs or pcLEDs.

LEDs or pcLEDs having dimensions in the plane of the array (e.g., side lengths) of less than or equal to about 50 microns are typically referred to as microLEDs, and an array of such microLEDs may be referred to as a microLED array.

In an array of pcLEDs, all pcLEDs may be configured to emit essentially the same spectrum of light. Alternatively, a pcLED array may be a multicolor array in which different pcLEDs in the array may be configured to emit different spectrums (colors) of light by employing different phosphor compositions. Similarly, in an array of direct emitting LEDs (i.e., not wavelength converted by phosphors) all LEDs in the array may be configured to emit essentially the same spectrum of light, or the array may be a multicolor array comprising LEDs configured to emit different colors of light.

The individual LEDs or pcLEDs in an array may be individually operable (addressable) and/or may be operable as part of a group or subset of (e.g., adjacent) LEDs or pcLEDs in the array.

An array of LEDs or pcLEDs, or portions of such an array, may be formed as a segmented monolithic structure in which individual LEDs or pcLEDs are electrically isolated or partially electrically isolated from each other by trenches and/or insulating material, but the electrically isolated or partially electrically isolated segments remain physically connected to each other by other portions of the semiconductor structure. For example, in such a monolithic structure the active region and a first semiconductor layer of a first conductivity type (n or p) on one side of the active region may be segmented, and a second unsegmented semiconductor layer of the opposite conductivity type (p or n) positioned on the opposite side of the active region from the first semiconductor layer. The second semiconductor layer may then physically and electrically connect the segmented structures to each other on one side of the active region, with the segmented structures otherwise electrically isolated from each other and thus separately operable as individual LEDs.

An LED or pcLED array may therefore be or comprise a monolithic multicolor matrix of individually operable LED or pcLED light emitters. The LEDs or pcLEDs in the monolithic array may for example be microLEDs as described above.

A single individually operable LED or pcLED or a group of adjacent such LEDs or pcLEDs may correspond to a single pixel (picture element) in a display. For example, a group of three individually operable adjacent LEDs or pcLEDs comprising a red emitter, a blue emitter, and a green emitter may correspond to a single color-tunable pixel in a display. In some variations a group of six individually operable adjacent LEDs or pcLEDs comprising two red emitters, two blue emitters, and two green emitters correspond to a single-color tunable pixel in a display, with the additional red, blue, and green emitters providing redundancy in case the other emitter of the same color fails.

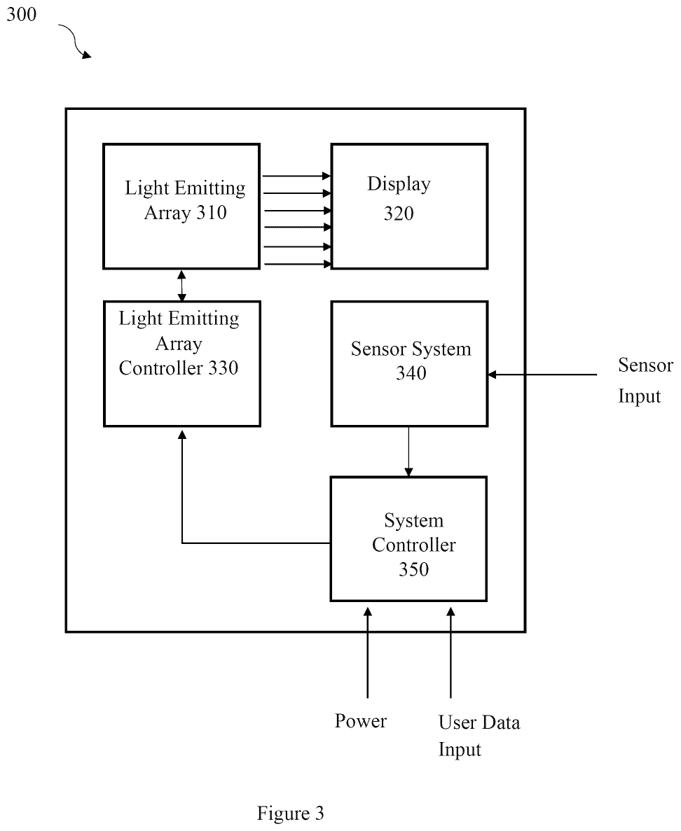

FIG. 3 schematically illustrates an example display system 300 that includes an array 310 of LEDs or pcLEDs that are individually operable or operable in groups, a display 320, a light emitting array controller 330, a sensor system 340, and a system controller 350. Array 310 may be a monolithic array, or comprise one or more monolithic arrays, as described above. The array may be monochromatic. Alternatively, the array may be a multicolor array in which different LEDs or pcLEDs in the array are configured to emit different colors of light, as described above. The array may therefore be or comprise a monolithic multicolor matrix of individually operable LED or pcLED light emitters, which may for example be microLEDs as described above. A single individually operable LED or pcLED or a group of adjacent such LEDs or pcLEDs in the array may correspond to a single pixel (picture element) in the display. For example, a group of three individually operable adjacent LEDs or pcLEDs comprising a red emitter, a blue emitter, and a green emitter may correspond to a single color-tunable pixel in the display. Similarly, to provide redundancy in the event of a defective LED or pcLED, a group of six individually operable adjacent LEDs or pcLEDs comprising two red emitters, two blue emitters, and two green emitters may correspond to a single color-tunable pixel in the display Array 310 can be used to project light in graphical or object patterns that can for example support AR/VR/MR systems.

Sensor input is provided to the sensor system 340, while power and user data input is provided to the system controller 350. In some embodiments modules included in system 300 can be compactly arranged in a single structure, or one or more elements can be separately mounted and connected via wireless or wired communication. For example, array 310, display 320, and sensor system 340 can be mounted on a headset or glasses, with the light emitting array controller and/or system controller 350 separately mounted.

System 300 can incorporate a wide range of optics (not shown) to couple light emitted by array 310 into display 320. Such optics may comprise, for example, a microlens array as disclosed and employed herein in combination with the LED or pcLED array. Any suitable optics may be used for this purpose.

Sensor system 340 can include, for example, external sensors such as cameras, depth sensors, or audio sensors that monitor the environment, and internal sensors such as accelerometers or two or three axis gyroscopes that monitor an AR/VR/MR headset position. Other sensors can include but are not limited to air pressure, stress sensors, temperature sensors, or any other suitable sensors needed for local or remote environmental monitoring. In some embodiments, control input through the sensor system can include detected touch or taps, gestural input, or control based on headset or display position.

In response to data from sensor system 340, system controller 350 can send images or instructions to the light emitting array controller 330. Changes or modification to the images or instructions can also be made by user data input, or automated data input as needed. User data input can include but is not limited to that provided by audio instructions, haptic feedback, eye or pupil positioning, or connected keyboard, mouse, or game controller.

As noted above, AR, VR, and MR systems may be more generally referred to as examples of visualization systems. In a virtual reality system, a display can present to a user a view of a scene, such as a three-dimensional scene. The user can move within the scene, such as by repositioning the user's head or by walking. The virtual reality system can detect the user's movement and alter the view of the scene to account for the movement. For example, as a user rotates the user's head, the system can present views of the scene that vary in view directions to match the user's gaze. In this manner, the virtual reality system can simulate a user's presence in the three-dimensional scene. Further, a virtual reality system can receive tactile sensory input, such as from wearable position sensors, and can optionally provide tactile feedback to the user.

In an augmented reality system, the display can incorporate elements from the user's surroundings into the view of the scene. For example, the augmented reality system can add textual captions and/or visual elements to a view of the user's surroundings. For example, a retailer can use an augmented reality system to show a user what a piece of furniture would look like in a room of the user's home, by incorporating a visualization of the piece of furniture over a captured image of the user's surroundings. As the user moves around the user's room, the visualization accounts for the user's motion and alters the visualization of the furniture in a manner consistent with the motion. For example, the augmented reality system can position a virtual chair in a room. The user can stand in the room on a front side of the virtual chair location to view the front side of the chair. The user can move in the room to an area behind the virtual chair location to view a back side of the chair. In this manner, the augmented reality system can add elements to a dynamic view of the user's surroundings.

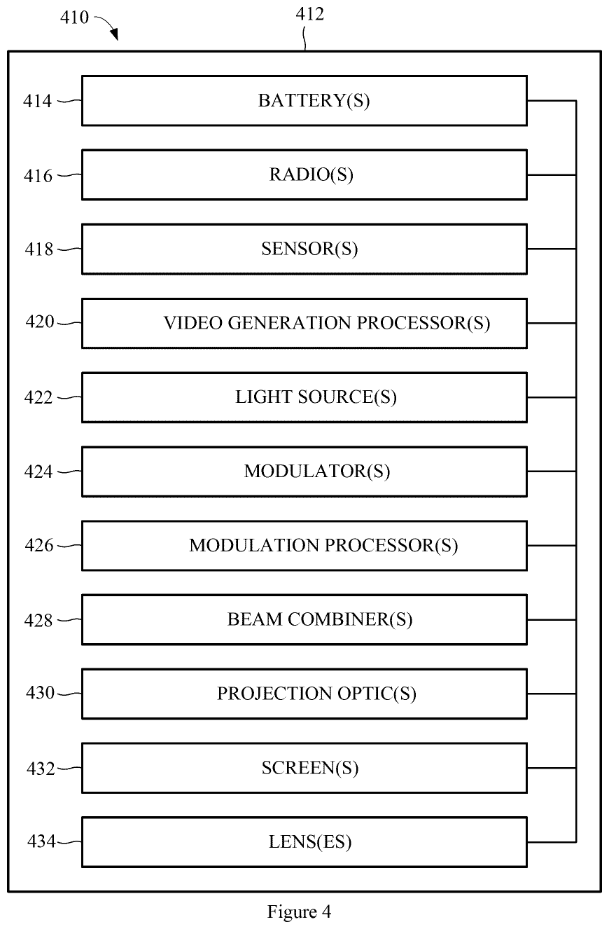

FIG. 4 shows a generalized block diagram of an example visualization system 410. The visualization system 410 can include a wearable housing 412, such as a headset or goggles. The housing 412 can mechanically support and house the elements detailed below. In some examples, one or more of the elements detailed below can be included in one or more additional housings that can be separate from the wearable housing 412 and couplable to the wearable housing 412 wirelessly and/or via a wired connection. For example, a separate housing can reduce the weight of wearable goggles, such as by including batteries, radios, and other elements. The housing 412 can include one or more batteries 414, which can electrically power any or all of the elements detailed below. The housing 412 can include circuitry that can electrically couple to an external power supply, such as a wall outlet, to recharge the batteries 414. The housing 412 can include one or more radios 416 to communicate wirelessly with a server or network via a suitable protocol, such as WiFi.

The visualization system 410 can include one or more sensors 418, such as optical sensors, audio sensors, tactile sensors, thermal sensors, gyroscopic sensors, time-of-flight sensors, triangulation-based sensors, and others. In some examples, one or more of the sensors can sense a location, a position, and/or an orientation of a user. In some examples, one or more of the sensors 418 can produce a sensor signal in response to the sensed location, position, and/or orientation. The sensor signal can include sensor data that corresponds to a sensed location, position, and/or orientation. For example, the sensor data can include a depth map of the surroundings. In some examples, such as for an augmented reality system, one or more of the sensors 418 can capture a real-time video image of the surroundings proximate a user.

The visualization system 410 can include one or more video generation processors 420. The one or more video generation processors 420 can receive, from a server and/or a storage medium, scene data that represents a three-dimensional scene, such as a set of position coordinates for objects in the scene or a depth map of the scene. The one or more video generation processors 420 can receive one or more sensor signals from the one or more sensors 418. In response to the scene data, which represents the surroundings, and at least one sensor signal, which represents the location and/or orientation of the user with respect to the surroundings, the one or more video generation processors 420 can generate at least one video signal that corresponds to a view of the scene. In some examples, the one or more video generation processors 420 can generate two video signals, one for each eye of the user, that represent a view of the scene from a point of view of the left eye and the right eye of the user, respectively. In some examples, the one or more video generation processors 420 can generate more than two video signals and combine the video signals to provide one video signal for both eyes, two video signals for the two eyes, or other combinations.

The visualization system 410 can include one or more light sources 422 that can provide light for a display of the visualization system 410. Suitable light sources 422 can include any of the LEDs, pcLEDs, LED arrays, and pcLED arrays discussed above, for example those discussed above with respect to display system 300.

The visualization system 410 can include one or more modulators 424. The modulators 424 can be implemented in one of at least two configurations.

In a first configuration, the modulators 424 can include circuitry that can modulate the light sources 422 directly. For example, the light sources 422 can include an array of light-emitting diodes, and the modulators 424 can directly modulate the electrical power, electrical voltage, and/or electrical current directed to each light-emitting diode in the array to form modulated light. The modulation can be performed in an analog manner and/or a digital manner. In some examples, the light sources 422 can include an array of red light-emitting diodes, an array of green light-emitting diodes, and an array of blue light-emitting diodes, and the modulators 424 can directly modulate the red light-emitting diodes, the green light-emitting diodes, and the blue light-emitting diodes to form the modulated light to produce a specified image.

In a second configuration, the modulators 424 can include a modulation panel, such as a liquid crystal panel. The light sources 422 can produce uniform illumination, or nearly uniform illumination, to illuminate the modulation panel. The modulation panel can include pixels. Each pixel can selectively attenuate a respective portion of the modulation panel area in response to an electrical modulation signal to form the modulated light. In some examples, the modulators 424 can include multiple modulation panels that can modulate different colors of light. For example, the modulators 424 can include a red modulation panel that can attenuate red light from a red light source such as a red light-emitting diode, a green modulation panel that can attenuate green light from a green light source such as a green light-emitting diode, and a blue modulation panel that can attenuate blue light from a blue light source such as a blue light-emitting diode.

In some examples of the second configuration, the modulators 424 can receive uniform white light or nearly uniform white light from a white light source, such as a white-light light-emitting diode. The modulation panel can include wavelength-selective filters on each pixel of the modulation panel. The panel pixels can be arranged in groups (such as groups of three or four), where each group can form a pixel of a color image. For example, each group can include a panel pixel with a red color filter, a panel pixel with a green color filter, and a panel pixel with a blue color filter. Other suitable configurations can also be used.

The visualization system 410 can include one or more modulation processors 426, which can receive a video signal, such as from the one or more video generation processors 420, and, in response, can produce an electrical modulation signal. For configurations in which the modulators 424 directly modulate the light sources 422, the electrical modulation signal can drive the light sources 424. For configurations in which the modulators 424 include a modulation panel, the electrical modulation signal can drive the modulation panel.

The visualization system 410 can include one or more beam combiners 428 (also known as beam splitters 428), which can combine light beams of different colors to form a single multi-color beam. For configurations in which the light sources 422 can include multiple light-emitting diodes of different colors, the visualization system 410 can include one or more wavelength-sensitive (e.g., dichroic) beam splitters 428 that can combine the light of different colors to form a single multi-color beam.

The visualization system 410 can direct the modulated light toward the eyes of the viewer in one of at least two configurations. In a first configuration, the visualization system 410 can function as a projector, and can include suitable projection optics 430 that can project the modulated light onto one or more screens 432. The screens 432 can be located a suitable distance from an eye of the user. The visualization system 410 can optionally include one or more lenses 434 that can locate a virtual image of a screen 432 at a suitable distance from the eye, such as a close-focus distance, such as 500 mm, 750 mm, or another suitable distance. In some examples, the visualization system 410 can include a single screen 432, such that the modulated light can be directed toward both eyes of the user. In some examples, the visualization system 410 can include two screens 432, such that the modulated light from each screen 432 can be directed toward a respective eye of the user. In some examples, the visualization system 410 can include more than two screens 432. In a second configuration, the visualization system 410 can direct the modulated light directly into one or both eyes of a viewer. For example, the projection optics 430 can form an image on a retina of an eye of the user, or an image on each retina of the two eyes of the user.

For some configurations of augmented reality systems, the visualization system 410 can include an at least partially transparent display, such that a user can view the user's surroundings through the display. For such configurations, the augmented reality system can produce modulated light that corresponds to the augmentation of the surroundings, rather than the surroundings itself. For example, in the example of a retailer showing a chair, the augmented reality system can direct modulated light, corresponding to the chair but not the rest of the room, toward a screen or toward an eye of a user.

As explained above, optical lenses have chromatic aberration, which is caused by inherent dispersion of the refractive index of lens materials. The consequence is that the focal length differs by color: a shorter focal length in the blue range and longer in red. As an example, a commercially available flint glass (relatively large dispersion) Schott SF-11 for example has refractive index of 1.82 for blue light and 1.78 for red light. The Focal length f of a plano-convex lens is given as

$$\frac{1}{f} = \frac{( n - 1 )}{R}$$

where n is the refractive index and R is the radius of curvature of the lens. For a lens formed from SF-11, the focal length difference between blue and red is calculated to be 1.05R. If R is 100 μm, the focal length difference is about 5 μm.

This means that when a blue microLED and a red microLED are placed at their own focal lengths (differing by about 5 μm, with the blue microLED closer) on an optical axis of an SF-11 lens element, collimated beams of blue and red are attained in the image space. A green microLED should be placed at a distance in between that for the blue and red microLEDs. Additional microLEDs emitting at wavelengths intermediate between blue and red can be properly distributed in the focal length scheme, depending on the light wavelength and corresponding refractive index of the lens. If wider (diverging) beams in the image space are desired rather than collimated beams, the placements of the microLEDs are adjusted accordingly (e.g. closer to the lens than the focal length).

If the microLEDs of different color are not all on the optical axis but instead displaced from each other perpendicular to the optical axis, the idea here still holds: a shorter wavelength microLED should be placed closer than a longer wavelength microLED to the microlens.

The inventor has recognized that the difference in focal lengths for such a micro lens for blue and red light, about 5 microns, is on the order of the thickness of the epitaxial structure of a microLED. Hence, the variation in distances required to achieve compensation for chromatic aberration of the microlens may be readily achieved in the fabrication of a microLED array.

As summarized above, this specification discloses light sources comprising microLEDs of two or more colors in combination with a shared microlens, arranged to compensate for chromatic aberration of the microlens by placing the microLEDs at different distances from the microlens. The microLEDs that emit shorter wavelength light are placed closer to the microlens than the microLEDs that emit longer wavelengths of light. MicroLED displays may similarly compensate for chromatic aberration, with a display comprising a microlens array and a plurality of pixels, with each pixel paired with one of the microlenses and the microLEDs within a pixel arranged to compensate for chromatic aberration of the pixel's lens.

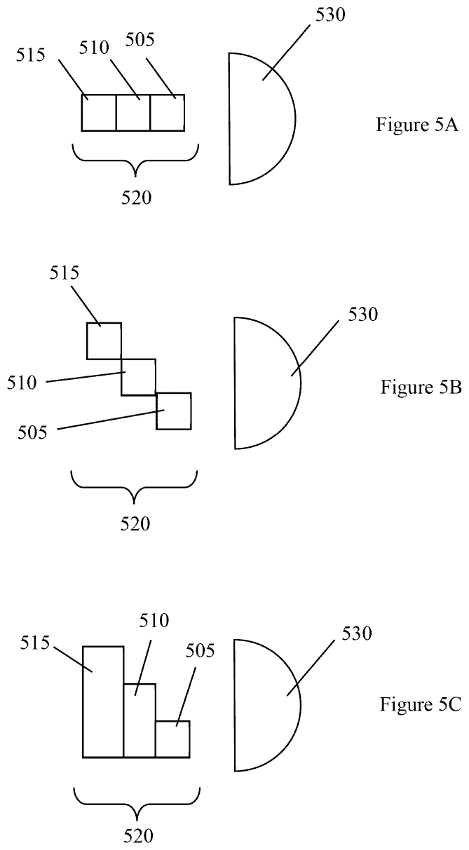

FIG. 5A, FIG. 5B, and FIG. 5C show schematic cross-sectional views of example light sources each comprising microLEDs 505, 510, and 515 of different colors grouped as a pixel 520 in combination with a shared microlens 530. The microLEDs are arranged to compensate for chromatic aberration of the microlens 530. MicroLED 505 emits light of a shorter wavelength than that emitted by microLED 510. MicroLED 510 emits light of a shorter wavelength than that emitted by microLED 515. MicroLED 505 is positioned with its front light emitting surface at a distance from microlens 530 less than the distance between the front light emitting surface of microLED 510 and microlens 530. MicroLED 510 is positioned with its front light emitting surface at a distance from microlens 530 less than the distance between the front light emitting surface of microLED 515 and microlens 530.

Each microLED may be placed, for example, at or near the focal point of microlens 530 for light of the peak wavelength emitted by the microLED.

The microLEDs may each emit light with a peak wavelength in the visible light spectrum. For example, in one variation microLED 505 emits blue light, microLED 510 emits cyan, green, or yellow light, and microLED 515 emits red light. Alternatively, one or more of the microLEDs may emit light with a peak wavelength in the infrared portion of the spectrum.

The differences between the distances from the different microLEDs to the microlens may be on the order of microns. If the microlens has a focal length of about 100 microns (discounting chromatic aberration), the distance from the front light emitting surface of microLED 505 to microlens 530 and the distance from the front light emitting surface of microLED 515 to microlens 530 may differ for example by about 3 microns to about 7 microns, for example about 5 microns if microLED 505 emits blue light and microLED 515 emits red light.

The microlens may have a focal length of, for example, about 1 mm to about 20 mm and a diameter of, for example, about 4 microns to about 200 microns.

The microLEDs may have light emitting surfaces having dimensions (e.g., side lengths) perpendicular to the optical axis of the microlens of, for example, about 2 microns to about 195 microns.

The ratio of the diameter of the microlens to the dimensions of the light emitting surfaces of the microLEDs perpendicular to the optical axis of the microlens may be, for example, greater than or equal to 10.

In the example of FIG. 5A, microLEDs 505, 510, and 515 are stacked on each other along the optical axis of microlens 530. This requires microLED 505 to transmit light emitted by microLED 510 and microLED 515, and also requires microLED 510 to transmit light emitted by microLED 515.

In the example of FIG. 5B microLED 510 is on the optical axis of microlens 530 and MicroLEDs 505 and 515 are each displaced perpendicularly from the optical axis of microlens 530. This arrangement does not require any of the microLEDs to transmit light emitted by any of the other microLEDs

In the example of FIG. 5C, microLEDs 505, 510, and 515 are stacked on each other but their (unobstructed) light emitting surfaces are displaced from each other in a plane perpendicular to the optical axis of microlens 530. This arrangement does not require any of the microLEDs to transmit light emitted by any of the other microLEDs.

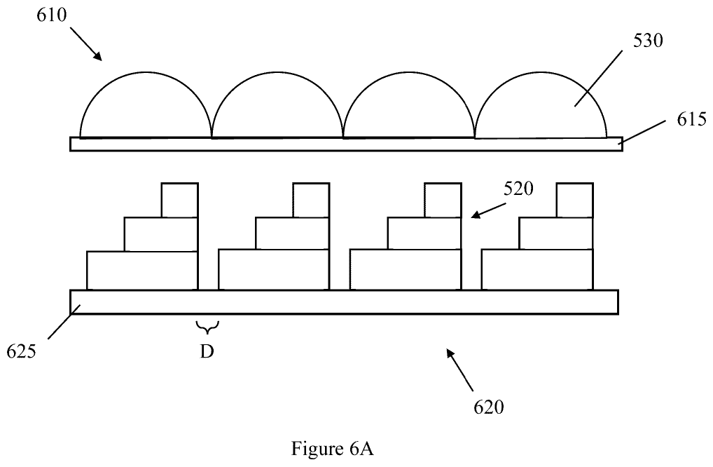

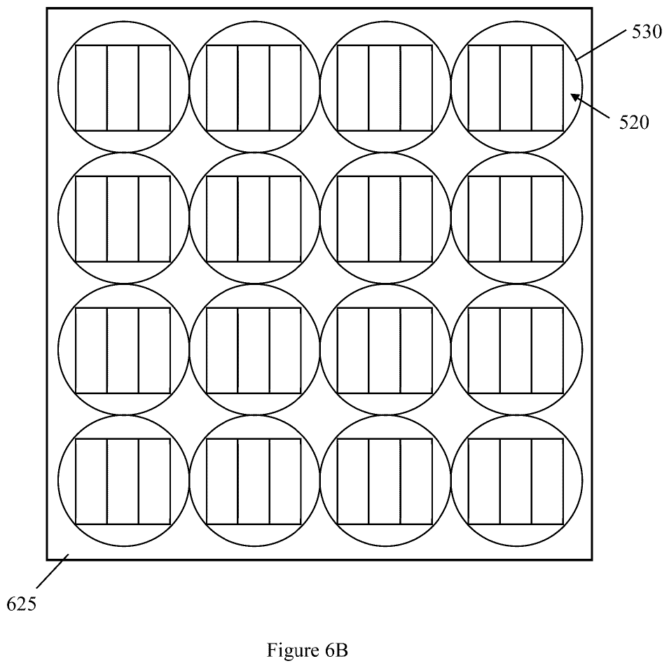

FIGS. 6A and 6B show, respectively, cross-sectional and top views of an example display comprising a microlens array 610 of microlenses 530 disposed on a substrate 615 and a microLED array 620 comprising a plurality of pixels 520 disposed on a substrate 625. Optionally, substrate 625 may be transparent to visible light. Each pixel 520 is paired with one of the microlenses 530, and the microLEDs within a pixel are arranged to compensate for chromatic aberration of the pixel's lens as described above. Such a display may be employed, for example, in microLED direct view and head-mount applications, or in other applications such as those described above in the background section.

The pixels 520 may be spaced apart from each other on substrate 620 by a distance D of, for example, about 2 microns to about 10 microns. This may correspond to a center-to-center pitch between adjacent pixels of, for example, about 4 microns to about 200 microns. Though shown adjacent to each other in the example of FIGS. 6A-6B, microlenses 530 in microlens array 610 may be spaced apart from each other on substrate 615, or otherwise separately arranged, to match the center-to-center pitch of the pixels.

Although the examples described with respect to FIGS. 5A-5C and 6A-6B employ microlenses, the same approach may be used to compensate for chromatic aberration in a conventionally sized lens having a diameter larger than a microlens, i.e., having a diameter greater than about 1 mm. Such a lens may have a focal length of, for example, about 1 mm to about 20 mm as described above with respect to examples employing microlenses. A conventionally sized lens may be employed in combination with two or more pixels, for example, with the microLEDs within the pixels arranged to compensate for chromatic aberration of the lens.

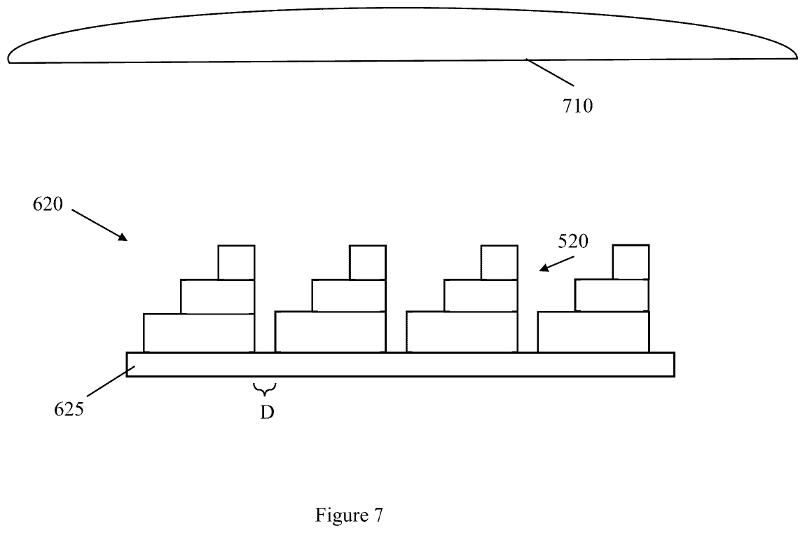

FIG. 7 shows a cross-sectional view of an example device comprising a microLED array 620 as described above in combination with a lens 710 that is arranged to collimate or partially collimate light emitted from a plurality of pixels 520 in the microLED array. Lens 710 is conventionally sized, i.e., larger than a microlens. The arrangement shown in FIG. 7 is similar to the arrangement shown in FIG. 6A, with the substitution of lens 710 for microlens array 610. The microLEDs within each pixel 520 are arranged to compensate for chromatic aberration of the lens 710 as described above with respect to a single pixel and a microlens. The arrangement shown in FIG. 7 may be a display, for example.

This disclosure is illustrative and not limiting. Further modifications will be apparent to one skilled in the art in light of this disclosure and are intended to fall within the scope of the appended claims.

What is claimed is:

1. A light source comprising:
a microlens;
a first microLED comprising a light emitting surface and configured to emit light having a first peak wavelength through its light emitting surface toward the microlens, the first microLED arranged at a first distance from the microlens for which the microlens collimates or partially collimates light at the first peak wavelength emitted by the first microLED through its light emitting surface;
a second microLED comprising a light emitting surface and configured to emit light having a second peak wavelength through its light emitting surface toward the microlens, the second microLED arranged at a second distance from the microlens for which the microlens collimates or partially collimates light at the second peak wavelength emitted by the second microLED through its light emitting surface, the second peak wavelength longer than the first peak wavelength and the second distance longer than the first distance; and
a third microLED comprising a light emitting surface and configured to emit light having a third peak wavelength through its light emitting surface toward the microlens, the third microLED arranged at a third distance from the microlens for which the microlens collimates or partially collimates light at the third peak wavelength emitted by the third microLED through its light emitting surface, the third peak wavelength longer than the second peak wavelength and the third distance longer than the second distance,
wherein the first distance is the focal length for the microlens at the first peak wavelength, the second distance is the focal length for the microlens at the second peak wavelength, and the third distance is the focal length for the microlens at the third peak wavelength.

2. The light source of claim 1, wherein the differences in length between the first distance, the second distance, and the third distance at least partially compensate for chromatic aberration exhibited by the microlens.

3. The light source of claim 1, wherein the first peak wavelength, the second peak wavelength, and the third peak wavelength are visible light wavelengths.

4. The light source of claim 3, wherein the first peak wavelength is a blue light wavelength and the third peak wavelength is a red light wavelength.

5. The light source of claim 4, wherein the difference in length between the first distance and the third distance is about 3 microns to about 7 microns.

6. The light source of claim 5, wherein the difference in length between the first distance and the third distance is about 5 microns.

7. The light source of claim 1, wherein the light emitting surface of the first microLED, the light emitting surface of the second microLED, and the light emitting surface of the third microLED are displaced from each other perpendicular to an optical axis of the microlens.

8. The light source of claim 1, wherein the second microLED is stacked on the third microLED and the first microLED is stacked on the second microLED.

9. The light source of claim 8, wherein the light emitting surface of the first microLED, the light emitting surface of the second microLED, and the light emitting surface of the third microLED are displaced from each other perpendicular to an optical axis of the microlens.

10. The light source of claim 1, wherein one or more of the microLEDs is a direct emitting microLED.

11. The light source of claim 1, wherein one or more of the microLEDs is a wavelength converted microLED.

12. The light source of claim 1, wherein the microlens has a diameter perpendicular to its optical axis of about 4 microns to about 200 microns.

13. The light source of claim 1, wherein the microlens has a focal length of about 1 mm to about 20 mm.

14. A display comprising:
a substrate,
a microlens array comprising a plurality of microlenses; and
a plurality of pixels disposed on the substrate, each paired with a different one of the microlenses, each pixel comprising:
a first microLED comprising a light emitting surface and configured to emit light having a first peak wavelength through its light emitting surface toward the pixel's microlens, the first microLED arranged at a first distance from the pixel's microlens for which the microlens collimates or partially collimates light at the first peak wavelength emitted by the first microLED through its light emitting surface;
a second microLED comprising a light emitting surface and configured to emit light having a second peak wavelength through its light emitting surface toward the pixel's microlens, the second microLED at a second distance from the pixel's microlens for which the microlens collimates or partially collimates light at the second peak wavelength emitted by the second microLED through its light emitting surface, the second peak wavelength longer than the first peak wavelength and the second distance longer than the first distance; and
a third microLED comprising a light emitting surface and configured to emit light having a third peak wavelength through its light emitting surface toward the pixel's microlens, the third microLED at a third distance from the pixel's microlens for which the microlens collimates or partially collimates light at the third peak wavelength emitted by the third microLED through its light emitting surface, the third peak wavelength longer than the second peak wavelength and the third distance longer than the second distance,
wherein the first distance is the focal length for the microlens at the first peak wavelength, the second distance is the focal length for the microlens at the second peak wavelength, and the third distance is the focal length for the microlens at the third peak wavelength.

15. The display of claim 14, wherein for each pixel the differences in length between the first distance, the second distance, and the third distance at least partially compensate for chromatic aberration exhibited by the pixel's microlens.

16. The display of claim 14, wherein for each pixel the first peak wavelength, the second peak wavelength, and the third peak wavelength are visible light wavelengths.

17. The display of claim 16, wherein for each pixel the first peak wavelength is a blue light wavelength and the third peak wavelength is a red light wavelength.

18. The display of claim 17, wherein for each pixel the difference in length between the first distance and the third distance is about 3 microns to about 7 microns.

19. The display of claim 18, wherein for each pixel the difference in length between the first distance and the third distance is about 5 microns.

20. A device comprising:
a substrate,
a lens; and
a plurality of pixels disposed on the substrate, each pixel comprising:
a first microLED comprising a light emitting surface and configured to emit light having a first peak wavelength through its light emitting surface toward the lens, the first microLED arranged at a first distance from the lens for which the lens collimates or partially collimates light at the first peak wavelength emitted by the first microLED through its light emitting surface;
a second microLED comprising a light emitting surface and configured to emit light having a second peak wavelength through its light emitting surface toward the lens, the second microLED arranged at a second distance from the lens for which the lens collimates or partially collimates light at the second peak wavelength emitted by the second microLED through its light emitting surface, the second peak wavelength longer than the first peak wavelength and the second distance longer than the first distance; and
a third microLED comprising a light emitting surface and configured to emit light having a third peak wavelength through its light emitting surface toward the lens, the third microLED arranged at a third distance from the lens for which the lens collimates or partially collimates light at the third peak wavelength emitted by the third microLED through its light emitting surface, the third peak wavelength longer than the second peak wavelength and the third distance longer than the second distance,
wherein the first distance is the focal length for the microlens at the first peak wavelength, the second distance is the focal length for the microlens at the second peak wavelength, and the third distance is the focal length for the microlens at the third peak wavelength.
